(19) United States
(12) Patent Application Publication
(10) Pub. No.: US 2013/0000717 A1
(43) Pub. Date: Jan. 3, 2013

(54) BACK REFLECTOR WITH NANOCRYSTALLINE PHOTOVOLTAIC DEVICE

(75) Inventors: Subhendu Guha, Auburn Hills, MI (US); Chi Yang, Troy, MI (US); Baojie Yan, Rochester Hills, MI (US)

(73) Assignee: United Solar Ovonic LLC, Auburn Hills, MI (US)

(21) Appl. No.: 13/537,954

(22) Filed: Jun. 29, 2012

Related U.S. Application Data
(60) Provisional application No. 61/503,770, filed on Jul. 1, 2011.

(51) Int. Cl. H01L 31/0232; H01L 31/18

(52) U.S. Cl. 136/256; 438/29; 257/E31.127

(57) ABSTRACT

A photovoltaic device and processes of manufacture are provided that employ particularly configured, textured back reflector structures that maintain a smooth, non-textured surface at the interface between the lowermost doped layer of semiconductor material and the intrinsic, light absorbing layer of nanocrystalline semiconductor material. The back reflector structure provides exhibit both superior short circuit current and a superior fill factor to a photovoltaic device such as those using nanocrystalline semiconductor materials.

### CROSS REFERENCE TO RELATED APPLICATIONS

This application depends from and claims priority to U.S. Provisional Application No. 61/503,770, filed Jul. 1, 2011, the entire contents of which are incorporated herein by reference.

### FIELD OF THE INVENTION

This invention relates to semiconductor devices in general and to photovoltaic devices in particular. More specifically, the subject invention relates to photovoltaic devices which include textured back reflector structures. And most specifically this invention relates to nanocrystalline silicon photovoltaic devices which include integrally formed, textured back reflector structures and in which the photovoltaic devices exhibit both superior short circuit current and a superior fill factor.

### BACKGROUND OF THE INVENTION

Photovoltaic devices include one or more layers of light absorbing semiconductor material. Many photovoltaic devices also include a multi-layered back reflecting structure adapted to redirect light which has passed through the various semiconductor layers of the device back through the semiconducting layers for additional absorption. These back reflector structures are, in some instances, configured to provide for diffused reflection of light so as to optimize absorption of photons and enhance internal reflection. Diffused reflection is typically accomplished by texturing one or more of the layers of the back reflector structure. In many instances, the back reflectors comprise a first layer of a highly light reflective metal including, without limitation, silver, aluminum, or copper. The highly reflective metal is then covered by a second layer of a transparent, electrically conductive material such as a transparent electrically conductive oxide including, without limitation, tin oxide or zinc oxide. Diffused reflection is accomplished in composite reflectors by texturing at least the upper surface of the transparent conductive oxide and in most instances by texturing the upper surfaces of both the light reflective metal layer and the transparent conductive oxide. Texturing can be done by changing the deposition conditions of the metal and/or the transparent conducting oxide, or by post-processing steps. Devices of this type are known in the prior art and are shown, for example, in U.S. Pat. No. 5,101,260. The disclosure of the '260 patent, as well as the disclosures of all prior art cited in connection with the prosecution thereof are incorporated herein by reference.

When the aforedescribed back reflector structures were developed, thin film photovoltaic devices were generally prepared utilizing multiple stacked cells wherein the layers of the active, light absorbing intrinsic semiconductor material was amorphous. Now, as the art has matured, at least some of the active layers of intrinsic semiconductor material of photovoltaic devices have come to be manufactured using nanocrystalline semiconductor material. However, the design of such back reflector structures has remained unchanged. As will be explained in detail hereinbelow, the present invention recognizes that where nanocrystalline semiconductor materials are utilized in photovoltaic devices, further improvements can be achieved through the use of particularly configured, textured back reflector structures which maintain a smooth, non-textured surface at the interface between the lowermost doped layer of semiconductor material and the intrinsic, light absorbing layer of nanocrystalline semiconductor material. These and other advantages of the invention will be apparent from the drawings, discussion, and description which follow.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

A photovoltaic device is provided that includes: a substrate; a layer of highly light reflective material on the substrate, the upper surface of the light reflective layer being textured so as to scatter light reflected therefrom; a layer of a transparent conductive oxide material having a bottom surface disposed on the light reflective surface of the substrate and an upper surface upon which a lower doped layer of a photovoltaic cell is disposed, the upper surface of the layer of transparent conductive oxide material having a texture substantially conformal with the texture of the upper surface of the light reflective material; and a doped layer of a nanocrystalline photovoltaic cell deposited on the textured upper surface of the layer of transparent conductive oxide material such that the bottom surface thereof has a texture substantially conformal with the texture of the upper surface of the transparent conductive oxide material and the upper surface of the doped layer having a smooth upper surface upon which other layers of the cell are deposited.

Also provided are process of fabricating a photovoltaic device including: providing a substrate; depositing a layer of highly light reflective material on the substrate; texturing the upper surface of the light reflective layer so as to scatter light reflected therefrom; disposing a layer of a transparent conductive oxide material having a bottom surface and a top surface, the bottom surface disposed on the light reflective surface of the substrate and the upper surface adapted to receive a lower doped layer of a photovoltaic cell; texturing the upper surface of the layer of transparent conductive oxide material, the texture being substantially conformal with the texture of the upper surface of the light reflective material; depositing a doped layer of a nanocrystalline photovoltaic cell on the textured upper surface of said layer of transparent conductive oxide material such that the bottom surface thereof has a texture substantially conformal with the texture of the upper surface of the transparent conductive oxide material; and planarizing the top layer of the n-type layer so as to provide a smooth, specular upper surface upon which the intrinsic layer of the cell can be deposited.

### BRIEF DESCRIPTION OF THE DRAWINGS

FIG. 1 illustrates a typical photovoltaic device of the prior art incorporating a non-diffuse back reflector structure;

FIG. 2 illustrates another photovoltaic device of the prior art which incorporates a diffuse back reflector structure;

FIG. 3 illustrates a photovoltaic device according to one embodiment;

FIG. 4A illustrates a composite reflective structure prepared including a substrate and a layer of transparent conductive oxide material according to one embodiment; and

FIG. 4B illustrates an upper surface a n-doped layer of one embodiment of a photovoltaic device of FIG. 4A following a polishing process.

### DESCRIPTION OF THE INVENTION

The following description of particular embodiment(s) is merely exemplary in nature and is in no way intended to limit the scope of the invention, its application, or uses, which may, of course, vary. The invention is described with relation to the non-limiting definitions and terminology included herein. These definitions and terminology are not designed to function as a limitation on the scope or practice of the invention but are presented for illustrative and descriptive purposes only. While the processes or devices are described as an order of individual steps or using specific materials, it is appreciated that described steps or materials may be interchangeable such that the description of the invention includes multiple parts or steps arranged in many ways as is readily appreciated by one of skill in the art.

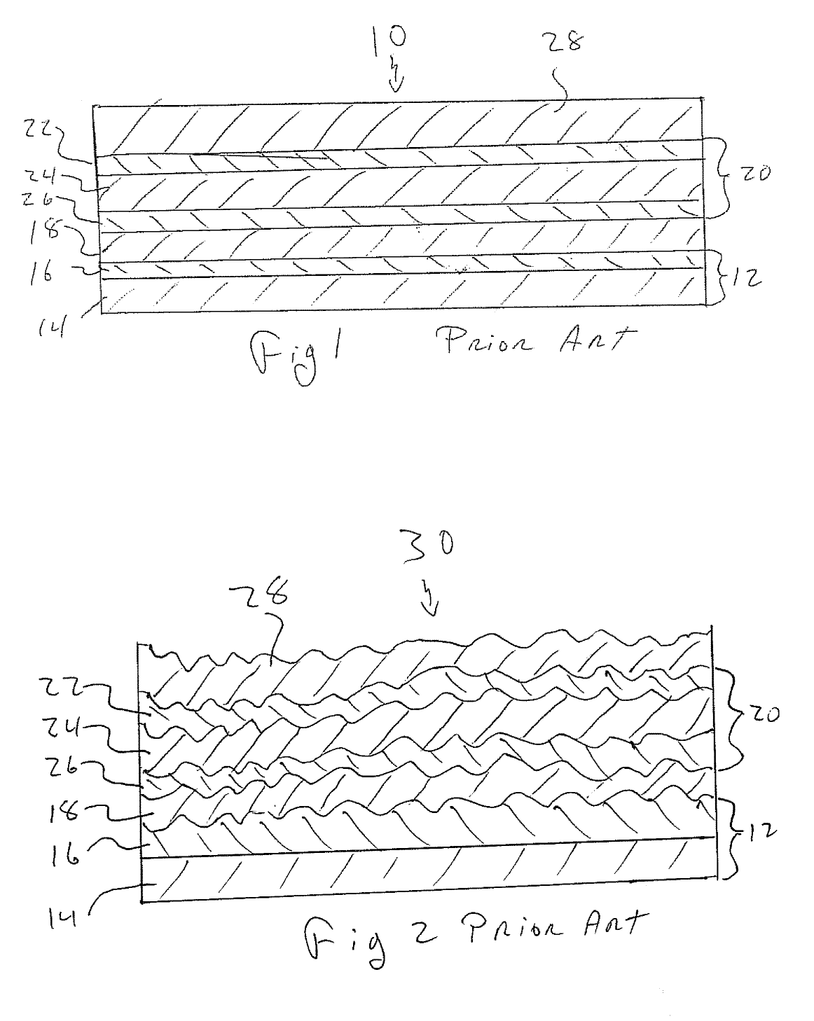

Referring now to FIG. 1, there is shown a typical photovoltaic device of the prior art incorporating a non-diffuse back reflector structure. The device 10 of FIG. 1 includes a substrate 12, in this instance a composite substrate comprised of a body of base or substrate material 14 which may be a layer of a metallic material such as stainless steel or a layer of polymeric material. Disposed atop the base 14 is a layer of reflective material 16 such as silver, copper, or aluminum. Disposed atop the reflective layer 16 is a layer of a transparent electrically conductive oxide material 18 such as a layer of zinc oxide, aluminum oxide, indium oxide, tin oxide, or mixtures thereof. Disposed atop the transparent conductive oxide layer 18 is a body of photovoltaic material 20, in this instance the photovoltaic device is formed as a triad of semiconductor layers comprising an uppermost (light incident) layer of p-type semiconductor material 22, a layer of substantially intrinsic semiconductor material 24, and a layer of n-type semiconductor material 26. This triad of layers of semiconductor material form what is known as a p-i-n type photovoltaic device and, as is known in the art, this triad of layers cooperates to generate a photovoltaic current when illuminated. It is to be understood that the photovoltaic body 20 as employed in the present invention may be otherwise configured but is generally formed with an intrinsic layer of substantially amorphous silicon material. Disposed atop the photovoltaic body 20 is a layer of top electrode material 28 which may also be a layer of transparent conductive oxide material such as indium tin oxide and the like.

Referring now to FIG. 2, there is shown another photovoltaic device of the prior art which incorporates a diffuse back reflector. This device is based upon the substrate 12 which, as in the prior figure, is a composite substrate including a base member 14 and a reflective layer 16. However, in this instance, the light reflective layer 16 is textured with features having a size chosen to at least induce and preferably maximize light scattering. These features are typically on the order of 0.1-5 microns. Disposed atop the textured reflective layer 16 is a layer of transparent conductive oxide material 18 and, as will be seen, this layer 18 will also include textured features as a result of being conformally deposited atop the light reflective layer 16. The remaining layers of the photovoltaic device 30 also show a texture similar to the subjacent layers of the back reflector structure. However, it will be noted that the layer of n-doped semiconductor also manifests a textured surface which conforms at least in part to the texture of the layer of transparent conductive oxide material 18. As illustrated, in some instances, one or more of the remaining semiconductor layers 24 and 22, and top electrode layer may manifest texture. The textured back reflector structure of FIG. 2 has heretofore been considered state of the art and is incorporated in a number of commercially available photovoltaic devices.

The present invention is based upon Applicants' finding that back reflector structures of the type shown in FIG. 2 have not been optimized for use with photovoltaic devices having the intrinsic layers thereof formed of nanocrystalline silicon, germanium or silicon germanium semiconductor material. Referring now to FIG. 3, there is shown a photovoltaic device 40 in accord with the present invention. The device 40 of FIG. 3 includes a composite back reflector structure and is formed on a substrate 12 as previously described. The substrate, in this instance, comprises a base member 14 which, as previously noted, may be a layer of metal or polymeric material. The base 14 has a light reflective layer 16 comprised of a metal such as silver, copper, or aluminum disposed thereupon. As in the FIG. 2 embodiment of the prior art, this layer is textured. It is to be noted that while FIG. 3 shows a substrate formed on a separate base layer 14 and a layer of reflective material 16, monolithic substrates based upon a textured reflective metal may be likewise be employed without departing from the spirit or scope of the present invention.

Disposed atop the textured metallic layer 16 is a layer of transparent conductive oxide material 18 as in the prior art which includes a conductive oxide layer 18 having an upper surface which generally similar to the texture of the subjacent metallic layer 16.

As in the prior embodiments, a semiconductor body 20 is disposed atop the upper surface of the layer of transparent conductive oxide material 18. As noted previously, this semiconductor body may be of various configurations operative to act as a photovoltaic device; and for purposes of illustration herein, it is described as being a triad of p-i-n layers of semiconductor materials 22, 24 and 26. In the device of the present invention, at least the intrinsic layer of the photovoltaic body 20 is comprised of a nanocrystalline material. In the illustrated embodiment, the bottommost layer of the triad is the n-type layer 26 and it is formed of amorphous or nanocrystalline semiconductor material such as an amorphous or nanocrystalline silicon, germanium, or a silicon-germanium alloy. In some instances at least part of the n-doped layer 26 may be comprised of an electrically-conductive, doped silicon dioxide material of the type known in the art. In other instances, a thin buffer layer of n-doped, electrically conductive silicon dioxide may be interposed between the n-doped layer 26 and the layer of substantially intrinsic material 26. As in the previous embodiment, the device 40 includes a top electrode 28, which is typically a layer of transparent electrically conductive oxide material.

It is to be noted that the n-type layer grows conformally atop and generally replicates the subjacent features or texture of the transparent conductive oxide layer 18. Very differently from prior art devices incorporating a back reflector structure, the upper surface of this n-type layer has been polished so as to remove the conformally grown texture or features. In that regard, it is referred to as a “smooth” surface, and it is to be understood that this surface is essentially free of texture features. For purposes of this disclosure “smooth” is defined as a surface having an RMS value of <15 nm. In particular instances, the surface is essentially free of vertical features having a size of 0.5 micron or greater; and in specific instances, it is essentially free of vertical features having a size of 0.2 micron or greater. By referring to the surfaces as being “essentially free” of the texture features, Applicant acknowledges that such surfaces may include some small number of texture features without departing from the present invention; however, such small number of features will not be sufficient to detract from the overall improvements achieved through the present invention.

As explained later, Applicant believes that by smoothening the upper surface of the n-type layer, the quality of the active, light absorbing intrinsic layer of nanocrystalline material can be significantly improved and resultant improvements in the performance characteristics of nanocrystalline based photovoltaic devices can be achieved. Specifically, devices in accord with the present invention will manifest both good short circuit currents and high fill factors. These performance characteristics represent commercially significant measurements of device performance indicative of maximized power output.

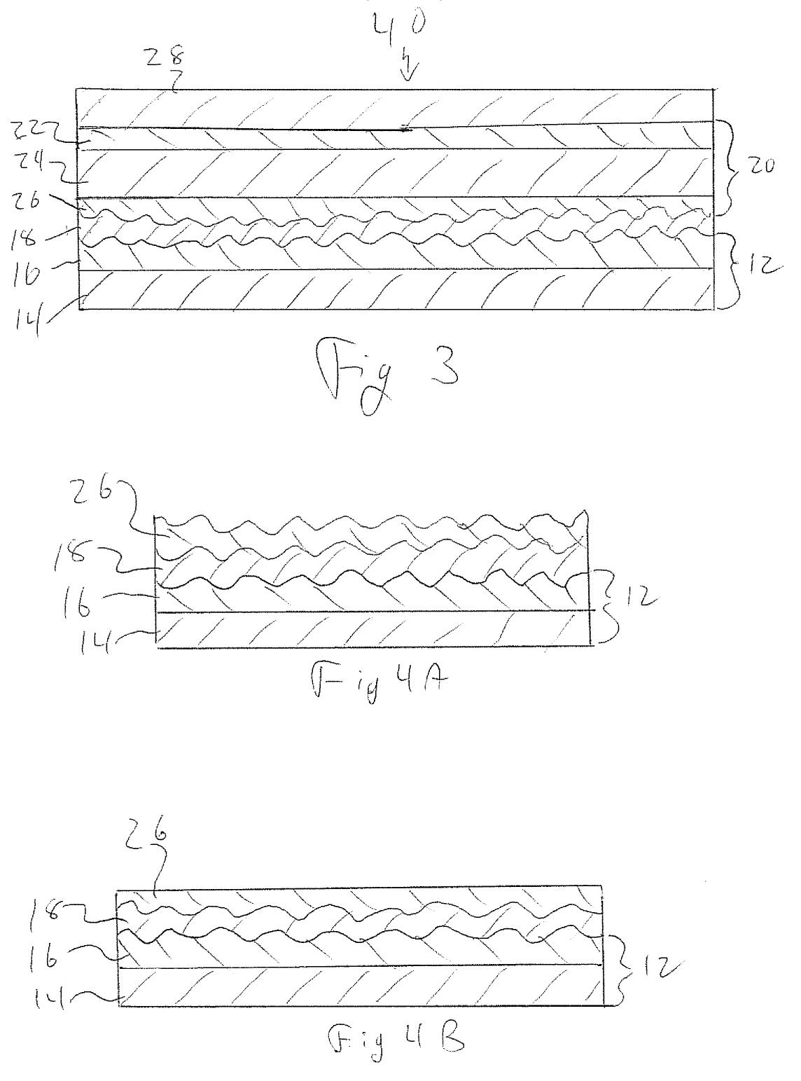

In typical substrate preparation processing, a layer of transparent conductive oxide material is deposited atop a textured reflective substrate, and the deposition processes employed (typically plating or vacuum deposition) tend to produce a conformal deposit so that the top surface of the transparent conductive oxide material is textured. FIG. 4A shows a composite reflective structure thus prepared as comprising a substrate 12 and a layer of transparent conductive oxide material 18. Subsequently, a radio frequency or vhf glow discharge vacuum deposition process is used to deposit the triad of layers of the photovoltaic device. As shown by the figures, the n-type layer is also conformally grown and has an upper surface that is similar to the features of the subjacent transparent conductive oxide.

In accord with one implementation of the present invention, the top surface of the n-type layer is polished so as to reduce the size of the texture features thereupon. This polishing may be accomplished by mechanical means such as by the use of abrasives or abrasive slurries, or it may be accomplished by chemical means such as by an etching process, which in some instances may be an electrochemical etching process. It also may be achieved by plasma etching. The aim is to smoothen the top surface of the n-type layer, but still keep it very thin. FIG. 4B shows the upper surface the n-doped layer of the photovoltaic device of FIG. 4A following the polishing process.

It has been found that the surface texture of the back reflector structure has a strong effect on the performance of nanocrystalline silicon based solar cells. Normally, nanocrystallites have a tendency to form elongated large clusters in an orientation perpendicular to the local surface. A textured surface could lead to crystallite collisions and thereby form defective materials. These defects would impede the collection of photogenerated carriers and decrease cell performance. Since a textured back reflector is required to effectively scatter incident light efficiently, cells with the highest current would have poorer fill factor. On the other hand, if one polishes the surface of the textured transparent conductive oxide so that the nanocrystalline silicon solar cell is deposited on a smooth surface, the cell would have a good fill factor, but the photogenerated current would be reduced since there is specular reflection from the smooth silicon-transparent conductive oxide interface. This is illustrated in Table 1.

In Table 1, V_{oc} is the open circuit voltage, FF is fill factor, J_{sc} (0 V) is the short circuit current density as obtained from quantum efficiency measurements with no bias applied to the cell, J_{sc} (−5 V) is the short circuit current as obtained with a bias of −5 V. Measurements were made both using a solar simulator with an AM1.5 spectrum and also with a 610 nm cut-on filter to allow light to enter the cell only beyond that 610 nm wavelength. The 610 nm filter was used because in a multi-junction cell incorporating nc-Si:H, this is the light that the lower component cell(s) will see.

TABLE 1
Solar Cell Parameters

| | | | | J_{sc}(0 | J_{sc}(−5 | Pₘₐₓ | Surface |
|---|---|---|---|---|---|---|---|
| Sam- | | V_{oc} | | V) mA/ | V) mA/ | (W/ | Con- |
| ple | Source | (V) | FF | cm² | cm² | cm²) | dition |
| 1 | Filter | 0.46 | 0.6 | 13.62 | 15.39 | 3.77 | Tex- |
| | 610 | | | | | | tured |
| 1 | AM 1.5 | 0.492 | 0.578 | 25.06 | 27.05 | 7.13 | Tex- |
| | | | | | | | tured |
| 2 | Filter | 0.475 | 0.65 | 13.54 | 13.93 | 4.18 | Po- |
| | 610 | | | | | | lished |
| 2 | AM 1.5 | 0.5 | 0.623 | 25.03 | 25.55 | 7.8 | Po- |
| | | | | | | | lished |

Sample 1 is a single-junction nanocrystalline photovoltaic cell grown on a conventional textured surface. The fill factor under the filtered light is relatively low (0.6) but the total absorption in the cell is high (15.39 mA/cm²) as evidenced by the short circuit current under the reverse bias when all the photo generated carriers are collected. In sample 2, the transparent conduction oxide has been polished so the cell is grown on a smooth surface. The fill factor has improved to 0.65 but the current drops to 13.93 mA/cm². As explained earlier, the increase in fill factor is caused by the better quality of the nanocrystalline material on the smooth surface; the drop in current is caused by the specular reflection at the silicon/transparent conduction oxide interface.

In order to design a cell with very high photo-conversion efficiency, it is necessary to have both higher FF and short circuit current. The following describes how this can be accomplished. In one embodiment of the instant invention, a thick highly doped n-type layer is grown onto the upper, textured surface of the layer of transparent conductive oxide material 18. Since this n-type layer usually grows conformally atop and matching the texture of the upper surface of the transparent conductive oxide material 18, the upper surface of the n-type layer will also match the texture of the underlying upper surface of the transparent conductive oxide layer 18. Now however the upper surface of the n-type layer is polished by plasma etching or by a chemical or mechanical process so that the n-type layer is thinned and the upper surface thereof is specular. Next the intrinsic layer of semiconductor material and the uppermost, light incident p-type layer are grown to complete the solar cell. In some cases, it may be necessary to deposit a thin n-type interfacial layer between the smooth upper surface of n-type layer and the intrinsic layer. Since the intrinsic layer will thereby be grown on a smooth surface, the quality of the intrinsic material will be good and the result will be a solar cell characterized by a good FF. On the other hand, since the refractive indices of the intrinsic and the n-type layers are very similar, there will be minimal specular reflection. Most of the reflection will be from the textured underlying layers of the back reflector structure and that will concurrently result in and provide a solar cell with high current density.

Note that although we have discussed an embodiment where the solar cell is made on a metal substrate, the same concept can be used for cells formed on a glass superstrate. In such a configuration, successive layers of p-type, intrinsic and n-type semiconductor material are deposited to form p-i-n solar cells on textured transparent oxide on glass. In such a case the bottom p-type layer is polished so as to allow the growth of superior quality intrinsic semiconductor material and the current will be large because of the scattering at the interface of the transparent conducting oxide and the p-type layer. Although the application discusses the polishing of the n-type silicon layer, there are other options where one can grow both the n and the i-layer and polish a substantial part of the i-layer and grow a remaining portion of the i-layer and the p-layer on the polished surface so that a substantial part of microcrystalline i-layer is grown on a smooth surface. The invention broadly covers growth of microcrystalline silicon on a polished surface with the same refractive index with an underlying scatterer.

The present invention has been described with reference to specific designs of multi-junction amorphous and nanocrystalline silicon, germanium and silicon germanium photovoltaic devices and specific layer configurations. It is to be understood that it may be otherwise implemented. For example, back reflector structures comprised of a smaller or larger number of layers may be employed. Or for another example, the substrate itself may be monolithic and incorporate a reflective texture on its upper surface. In other instances, multiple layers may be employed as a reflective body; and in further instances, additional layers may be interposed between the reflective surface and the transparent conductive oxide. All of such embodiments, modifications, and variations are within the scope of the present invention. It is the following claims, including all equivalents, which define the scope of the invention.

1. A photovoltaic device comprising:
a substrate;
a layer of highly light reflective material on said substrate, the upper surface of said light reflective layer being textured so as to scatter light reflected therefrom;
a layer of a transparent conductive oxide material having a bottom surface disposed on the light reflective surface of the substrate and an upper surface upon which a lower doped layer of a photovoltaic cell is disposed, the upper surface of said layer of transparent conductive oxide material having a texture substantially conformal with the texture of the upper surface of the light reflective material; and
a doped layer of a nanocrystalline photovoltaic cell deposited on the textured upper surface of said layer of transparent conductive oxide material such that the bottom surface thereof has a texture substantially conformal with the texture of the upper surface of the transparent conductive oxide material and the upper surface of the doped layer having a smooth upper surface upon which other layers of the cell are deposited.

2. The device of claim 1, wherein the textured, light reflective layer and the textured transparent conductive oxide both include vertical features having a size in the range of 0.1-5 microns.

3. The device of claim 2, wherein said substrate is comprised of stainless steel and/or a polymeric material and said light reflective material is formed from one or more of aluminum, copper, and silver.

4. The device of claim 1, wherein said transparent conductive oxide layer is formed as an oxide of zinc.

5. The device of claim 1, wherein said layer of transparent conductive oxide material has a thickness in the range of 500-10000 angstroms.

6. The device of claim 1, wherein the intrinsic layer of the photovoltaic cell is formed of nanocrystalline material.

7. The device of claim 1, wherein said nanocrystalline material is selected from the group comprising silicon, germanium and silicon-germanium.

8. The device of claim 1, wherein the doped layer adjacent to the transparent conductive oxide is n-type.

9. The device of claim 1 in which a thin buffer n-type, buffer layer is grown before the nanocrystalline intrinsic material is deposited thereupon.

10. The device of claim 9, wherein the buffer layer is comprised of a doped, silicon oxide material.

11. The device of claim 1, wherein the doped layer adjacent to the transparent conductive oxide is at least partially comprised of a doped, silicon dioxide material.

12. The device of claim 9, wherein the smooth surface of said n-type layer is essentially free of features having a vertical size greater than 0.5 micron and, in particular instances, a size of greater than 0.01 micron.

13. The device of claim 1, wherein said smooth surface of said doped layer is a surface which has been polished by chemical, mechanical or plasma means.

14. A method for the fabrication of a photovoltaic device, said method comprising the steps of:
providing a substrate;
depositing a layer of highly light reflective material on said substrate;
texturing the upper surface of said light reflective layer so as to scatter light reflected therefrom;
disposing a layer of a transparent conductive oxide material having a bottom surface and a top surface, the bottom surface disposed on the light reflective surface of the substrate and the upper surface adapted to receive a lower doped layer of a photovoltaic cell;
texturing the upper surface of said layer of transparent conductive oxide material, said texture being substantially conformal with the texture of the upper surface of the light reflective material;
depositing a doped layer of a nanocrystalline photovoltaic cell on the textured upper surface of said layer of transparent conductive oxide material such that the bottom surface thereof has a texture substantially conformal with the texture of the upper surface of the transparent conductive oxide material; and
planarizing the top layer of the n-type layer so as to provide a smooth, specular upper surface upon which the intrinsic layer of the cell can be deposited.

15. The method of claim 14, wherein said step of planarizing the upper surface of the doped layer includes the steps of depositing a thick doped layer and then polishing said doped layer to remove the texture therefrom.

16. The method of claim 15, wherein the step of polishing said doped layer comprises chemically and/or mechanically polishing said layer.

17. The method of claim 15, wherein the step of polishing said doped layer comprises polishing said layer so that it is essentially free of vertical features having a size of greater than 1 micron and, in particular instances, a size of greater than 0.01 micron.

18. The method of claim 14, wherein the step of depositing said doped layer comprises depositing the doped material thereof in a plasma deposition process and then plasma etching the upper surface thereof to remove the surface features.

19. A photovoltaic device made by the method of claim 14.
